(19) United States
(12) Patent Application Publication
(10) Pub. No.: US 2009/0267114 A1
(43) Pub. Date: Oct. 29, 2009

(54) FIELD EFFECT TRANSISTOR

(75) Inventors: Tatsuo Nakayama, Tokyo (JP); Yuji Ando, Tokyo (JP); Hironobu Miyamoto, Tokyo (JP); Yasuhiro Okamoto, Tokyo (JP); Takashi Inoue, Tokyo (JP); Kazuki Ota, Tokyo (JP); Yasuhiro Murase, Tokyo (JP); Naotaka Kuroda, Tokyo (JP)

Correspondence Address: YOUNG & THOMPSON, 209 Madison Street, Suite 500, ALEXANDRIA, VA, 22314, US

(73) Assignee: NEC Corporation, Tokyo (JP)

(21) Appl. No.: 12/295,104

(22) PCT Filed: Mar. 23, 2007
(86) PCT No.: PCT/JP2007/000284

§ 371 Date: Sep. 29, 2008

(30) Foreign Application Priority Data
Mar. 28, 2006 (JP) 2006-088274

(51) Int. Cl. H01L 29/772; H01L 29/205

(52) U.S. Cl. 257/192; 257/288; 257/E29.242

(57) ABSTRACT

A field effect transistor 100 includes a group III-V nitride semiconductor layer structure containing a hetero junction, a source electrode 105 and a drain electrode 106 formed on the group III-V nitride semiconductor layer structure to be spaced apart from each other; a gate electrode 110 arranged between the source electrode 105 and the drain electrode 106, and an insulating layer 107 provided over, and in contact with, the group III-V nitride semiconductor layer structure in a region between the gate electrode 110 and the drain electrode 106 or in a region between the source electrode 105 and the gate electrode 110. A portion of the gate electrode 110 is buried in the group III-V nitride semiconductor layer structure, and a side edge of the gate electrode in an interface of the group III-V nitride semiconductor layer and the insulating layer 107 is spaced apart from the gate electrode 110.

### TECHNICAL FIELD

The present invention relates to a field effect transistor.

### BACKGROUND ART

A structure, which employs a silicon nitride (SiN) film as a passivation film in a hetero-junction field effect transistor (HJFET) structure having a hetero junction of aluminum gallium nitride/gallium nitride (AlGaN/GaN) for the purpose of reducing an electric current collapse, is reported.

A structure that employs an SiNx film disposed on an AlGaN/GaN as a passivation film, in which a gate electrode is buried, is reported in Non-patent literature 1. FIG. 4 is a cross-sectional view, illustrating a configuration of a field effect transistor corresponding to the structure described in such literature.

In a field effect transistor 1000 shown in FIG. 4, an aluminum nitride (AlN) nucleation layer 1002, an (Al, Ga) N buffer layer 1003 and a GaN buffer layer 1004 are grown on a silicon (Si) substrate 1001, and a formation of a source electrode 1006 and a drain electrode 1007 and an isolation of the elements are conducted, and then an SiNx insulating film 1008 is formed, and a dry etching process is conducted to remove a portion of the SiNx insulating film, and further a gate electrode 1009 is buried to form a device.

### [Non-Patent Literature 1]

Entitled “Material, Process, and Device Development of GaN-Based HFETs on Silicon Substrates”, written by 15 authors including J. W. Johnson, Electrochemical Society Proceedings, pp. 2004-2006, vol. 405.

However, in the conventional field effect transistor, more interface states are present in SiNx/AlGaN interface by an influence of a piezoelectric effect of AlGaN, as compared with other group III-V compound semiconductor such as gallium arsenide (GaAs), and thus exhibits an electric potential that is substantially equivalent to a potential of a drain electrode around the gate electrode. Thus, a leakage current is generated via the SiNx/AlGaN interface in a section that includes both the SiNx/AlGaN interface and the gate electrode, instead of a Schottky contact-like leakage through the AlGaN layer, eventually causing a gate leakage.

### DISCLOSURE OF THE INVENTION

According to one aspect of the present invention, there is provided a field effect transistor, comprising: a group III-V nitride semiconductor layer structure containing a hetero junction; a source electrode and a drain electrode formed on the group III-V nitride semiconductor layer structure to be spaced apart from each other; a gate electrode disposed between the source electrode and the drain electrode; and a covering layer provided over, and in contact with, the group III-V nitride semiconductor layer structure in a region between the gate electrode and the drain electrode or in a region between the source electrode and the gate electrode, wherein a portion of the gate electrode is buried in the group III-V nitride semiconductor layer structure, and wherein a gate electrode side edge in an interface of the group III-V nitride semiconductor layer with the covering layer is spaced apart from the gate electrode.

Since the gate electrode is not in contact with the interface between the group III-V nitride semiconductor layer and the covering layer having more interface states created therein in the present invention, no leakage path through such interface is present, and thus a Schottky characteristic is exhibited, in which all the gate current flows through a structure including a Schottky electrode—the group III-V nitride semiconductor layer. Thus, a reduction in the gate leakage current can be achieved, allowing an operation at higher voltage and/or an operation at higher power.

In addition to above, any arbitrary combination of each of these constitutions or conversions between the categories of the invention such as a process, a device, a method for utilizing the device and the like may also be within the scope of the present invention.

As described above, since the side edge of the gate electrode in the interface of the group III-V nitride semiconductor layer and the covering layer is spaced apart from the gate electrode according to the present invention, a generation of a gate leakage current can be effectively inhibited.

### BRIEF DESCRIPTION OF THE DRAWINGS

The above and other objects, advantages and features of the present invention will be more apparent from the following description of certain preferred embodiments taken in conjunction with the accompanying drawings.

FIG. 1 is a cross-sectional view, illustrating a configuration of a semiconductor device in an embodiment;

FIG. 2 is a cross-sectional view, illustrating a configuration of a semiconductor device in an embodiment;

FIG. 3 is a cross-sectional view, illustrating a process for manufacturing a semiconductor device of FIG. 1;

FIG. 4 is a cross-sectional view, illustrating a configuration of a conventional semiconductor device; and

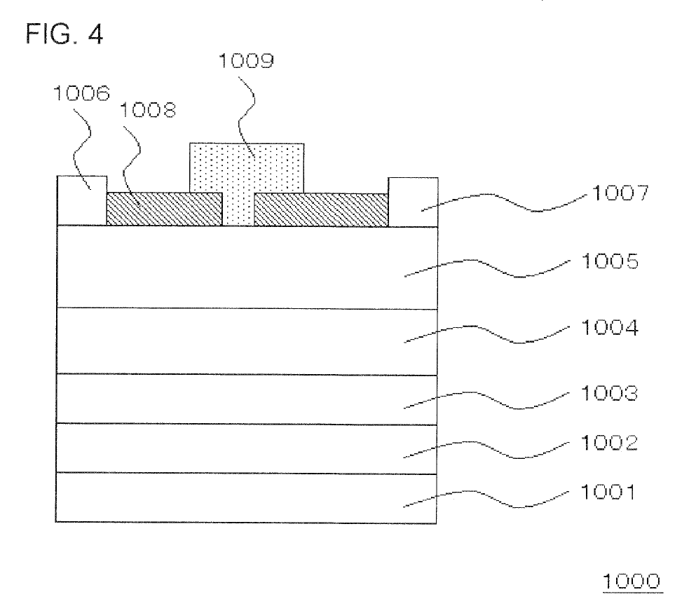

FIG. 5 is a cross-sectional view, illustrating a configuration of a semiconductor device in an embodiment.

### BEST MODE FOR CARRYING OUT THE INVENTION

Preferable embodiments of the present invention will be described below, in reference to the annexed figures. In all figures, an identical numeral is assigned to an element commonly appeared in the figures, and the detailed description thereof will not be repeated.

### First Embodiment

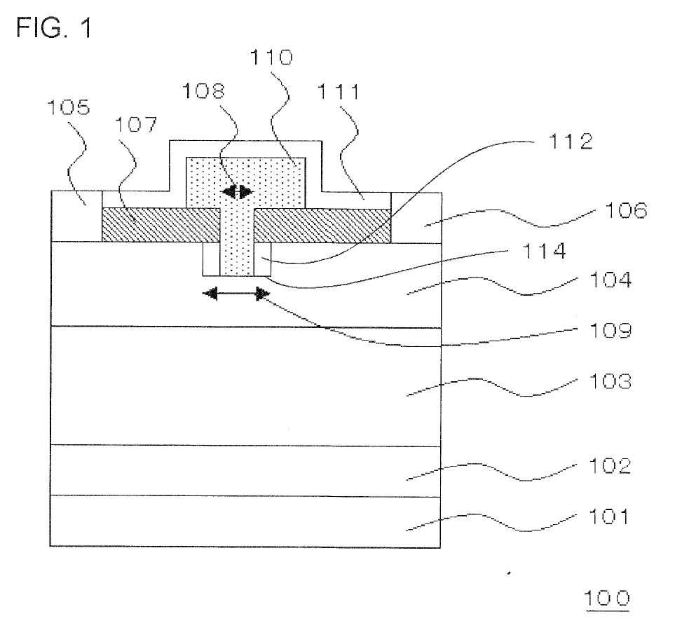

FIG. 1 is a cross-sectional structure diagram, illustrating a configuration of operation of the present invention. A field effect transistor 100 shown in FIG. 1 includes a group III-V nitride semiconductor layer structure (a buffer layer 102, a carrier-traveling layer 103 and a carrier-supplying layer 104) having a hetero junction. The group III-V nitride semiconductor layer structure includes an electron-travelling layer (a carrier-traveling layer 103), and an electron-supplying layer (a carrier-supplying layer 104) provided on, and in contact with, the carrier-traveling layer 103.

A source electrode 105 and a drain electrode 106 are formed to be spaced apart from each other on the carrier-supplying layer 104 that constitutes the group III-V nitride semiconductor layer structure. In addition, a gate electrode 110 is arranged between the source electrode 105 and the drain electrode 106. A portion of the gate electrode 110 is buried in the group III-V nitride semiconductor layer structure, and more specifically in the carrier-supplying layer 104.

In a region between the gate electrode 110 and the drain electrode 106 or in a region between the source electrode 105 and the gate electrode 110, a covering layer (insulating film 107) is provided so as to be in contact with the carrier-supplying layer 104 that constitutes the group III-V nitride semiconductor layer structure. In the present embodiment, an exemplary implementation employing a single layer of an insulating film for the covering layer will be described.

In addition to above, while exemplary implementations configured to providing the insulating film 107 on the carrier-supplying layer 104 over the entire region between the gate electrode 110 and the drain electrode 106 and the entire region between the source electrode 105 and the gate electrode 110 in the present embodiment and the subsequent embodiments, the insulating film 107 may not be formed over the entire region between the gate electrode 110 and the drain electrode 106 or over the entire region between the source electrode 105 and the gate electrode 110.

In the field effect transistor 100, the side edge of the gate electrode 110 in the interface of the carrier-supplying layer 104 and the insulating film 107 is spaced apart from the gate electrode 110. In addition, the insulating film 107 is provided so as to be in contact with the side surface of the gate electrode 110, and the side surface of carrier-supplying layer 104 is spaced apart from the gate electrode 110 under a region thereof contacting with the insulating film 107.

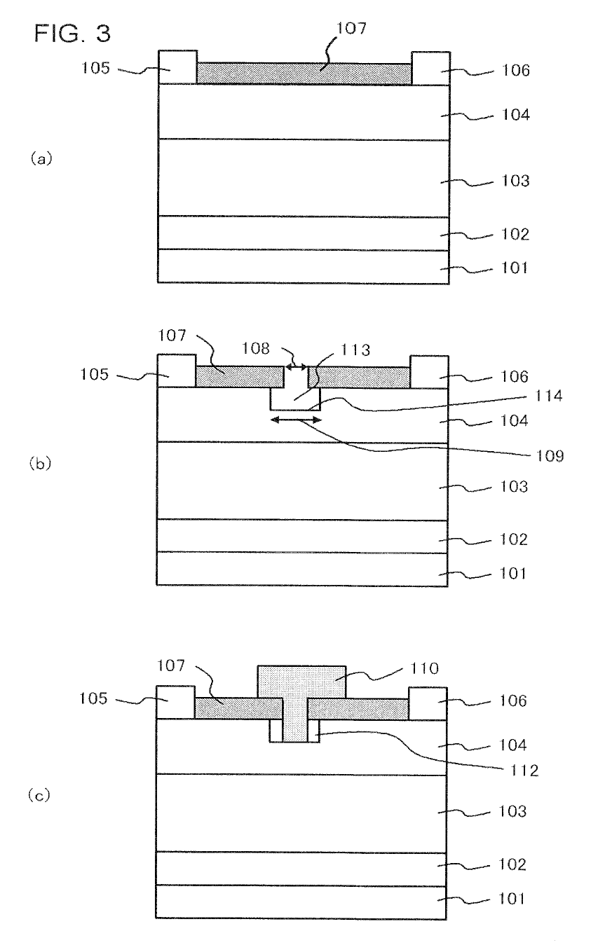

In addition, a concave portion (a concave portion 113 in FIG. 3(b)) is provided in the carrier-supplying layer 104, and the gate electrode 110 is provided so as to be in contact with a bottom surface of the concave portion 113 in a cross-sectional view along the gate length, and a gap 112 is provided between the side surface of the gate electrode 110 and the side surface of the concave portion 113. The side surface of the gate electrode 110 is spaced apart from the side surface of the carrier-supplying layer 104 by the gap 112, and is configured so as have no contact therebetween. In the cross-sectional view along the gate length, the length of the gap 112 is, for example, larger than 0 nm and smaller than 50 nm.

The concave portion 113 is formed by, for example, a recess etch process as will be discussed later, and in a cross-sectional view along the gate length, the side surface of the concave portion 113 is pulled back from the side surface of the gate electrode 110 toward the side of the source electrode 105 or the side of the drain electrode 106.

In addition, the insulating film 107 is provided so as to be in contact with the side surface of the drain electrode 106 of the gate electrode 110, and the gate electrode 110 includes a field plate formed over the insulating layer 107 to protrude toward the side of the drain electrode 106 to form a visor-like shape.

Further description of the specific configuration of the each of the layers will be described below. In the present embodiment, the group III-V nitride semiconductor layer structure is composed of the buffer layer 102, the carrier-traveling layer 103 and the carrier-supplying layer 104, which are deposited in this sequence on the substrate 101.

For example, sapphire, silicon carbide, gallium (III) nitride (GaN), aluminum nitride (AlN) or the like may be typically employed for the substrate 101 of the present embodiment.

In addition, the buffer layer 102 is composed of a first group III-V nitride semiconductor material. Typical material for the first group III-V nitride semiconductor material includes, for example, GaN, indium nitride (InN), AlN and a mixture of these three group III-V nitride semiconductor materials. However, for forming the first group III-V nitride semiconductor material, a nucleation layer composed of GaN, InN, AlN and a mixture of these three group III-V nitride semiconductor materials may be disposed between the substrate 101 and the buffer layer 102. In addition, n-type impurity such as, for example, silicon (Si), sulfur (S), oxygen (O), selenium (Se) and the like and/or p-type impurity such as, for example, beryllium (Be), carbon (C), magnesium (Mg) and the like may be added in the first group III-V nitride semiconductor material.

The carrier-traveling layer 103 is composed a second group III-V nitride semiconductor material. Typical material for the second group III-V nitride semiconductor material includes, for example, GaN, InN, AlN and a mixture of these three group III-V nitride semiconductor materials. In addition, n-type impurity such as, for example, Si, S, O, Se and the like and/or p-type impurity such as, for example, Be, C, Mg and the like may be added in the second group III-V nitride semiconductor material. However, the impurity concentration may be preferably 1×10¹⁷ cm⁻³ or lower, in terms of reducing degradation in mobility of electron due to an influence of coulomb scattering caused by an increase in impurity concentration in the second group III-V nitride semiconductor material.

In addition, the carrier-supplying layer 104 is composed of a third group III-V nitride semiconductor material. The carrier-supplying layer 104 may be, composed of, for example, a wurtzite form group III-V nitride semiconductor material. Typical third group III-V nitride semiconductor material includes, for example, GaN, InN, AlN and a mixture of these three group III-V nitride semiconductor materials. Alternatively, AlGaN, indium gallium nitride (InGaN), aluminum gallium indium nitride (AlGaInN) and the like may be employed for the third group III-V nitride semiconductor material. However, in the present embodiment, the third group III-V nitride semiconductor material is composed of a material or a composition exhibiting smaller electron affinity than the second group III-V nitride semiconductor material. In addition, n-type impurity such as, for example, Si, S, O, Se and the like and/or p-type impurity such as, for example, Be, C, Mg and the like may be added in the third group III-V nitride semiconductor material.

A specific example of a combination of the carrier-traveling layer 103 and the carrier-supplying layer 104 typically includes a configuration employing a GaN layer for the carrier-traveling layer 103 and an AlGaN layer for the carrier-supplying layer 104.

Further, the group III-V nitride semiconductor layer structure is configured of a chemical compound that is capable of generating piezo-electric charge in a region that contacts with the bottom surface of the gate electrode 110.

Further, typical material for the insulating film 107 includes a chemical compound composed of, for example, one or more of Si, Mg, hafnium (Hf), Al, titanium (Ti) and tantalum (Ta) with one or more of oxygen (O) and nitrogen (N). Specifically, a chemical compound containing Si and N is included, and more specifically, SiN film, silicon oxynitride (SiON) film and silicon carbonitride (SiCN) film are included. This can provide further effective inhibition of a collapse that may be generated between the gate electrode 110 and the drain electrode 106, so that an improved transistor exhibiting a reduced electric current collapse and higher output with lower gate leakage current can be obtained.

Further, typical material for the passivation film 111 includes a chemical compound composed of, for example, one or more of Si, Mg, Hf, Al, Ti and Ta with one or more of O and N. Further, an organic material such as an organic resin film and the like may be employed for the passivation film 111.

Next, the process for manufacturing the semiconductor device 100 will be described in reference to FIG. 1 and FIG. 3(a) to FIG. 3(c). FIG. 3(a) to FIG. 3(c) are cross-sectional views, illustrating the process for manufacturing the field effect transistor 100 shown in FIG. 1.

First of all, as shown in FIG. 3(a), the buffer layer 102 composed of the first group III-V nitride semiconductor material, the carrier-traveling layer 103 composed of the second group III-V nitride semiconductor material, and the carrier-supplying layer 104 composed of the third group III-V nitride semiconductor material are consecutively formed on the substrate 101. Thereafter, the source electrode 105 and the drain electrode 106 are formed on the carrier-supplying layer 104. Further, the insulating film 107 is deposited on the carrier-supplying layer 104 in the region between the source electrode 105 and the drain electrode 106.

Next, as shown in FIG. 3(b), a recess etch process is conducted to form a concave portion 113 extending through the insulating film 107 over the interior of the carrier-supplying layer 104 in a predetermined region between the source electrode 105 and the drain electrode 106. In such case, a predetermined region of the insulating film 107 is selectively removed to form a through hole, and further, the portion of the carrier-supplying layer 104 in the region right under such through hole is removed to form a recess surface 114 in the carrier-supplying layer 104.

Further, when the recess surface 114 is formed, the concave portion 113 is formed so that the width of the recess surface 114, that is a recess width 109, is larger than the width of the opening 108 in the insulating film 107 in a cross-sectional view along the gate length.

More specifically, first of all, a mask serving as a region for forming of the gate electrode 110 is formed on the insulating film 107, and the insulating film 107 is selectively etched off in the region for forming the gate electrode 110. In such case, for example, an etchant gas for selectively etching the insulating film 107 over the carrier-supplying layer 104 is employed to conduct a dry etching process. When the insulating film 107 is a film containing silicon such as silicon dioxide (SiO₂), SiN and the like, typical etchant gas includes, for example, carbon tetrafluoride (CF₄) or sulfur hexafluoride (SF₆).

Subsequently, the mask formed on the insulating film 107 is removed. Then, the carrier-supplying layer 104 is etched to a predetermined depth through a mask of the insulating film 107. In such case, for example, an etchant gas for selectively etching the carrier-supplying layer 104 over the insulating film 107 is employed to conduct a dry etching process. When the insulating film 107 is a film containing silicon such as SiO₂, SiN and the like, typical etchant gas includes, for example, a chlorine-containing gas. This allows etching of the carrier-supplying layer 104 along the depth direction and also allows a side etching, so that the concave portion 113 of a tapered geometry having larger diameter in the lower portion under the insulating film 107 is formed.

After the concave portion 113 is formed in this way, a gate electrode 110 is formed to protrude above the insulating film 107, while region corresponding to the opening width 108 in the insulating film 107 in the recess surface 114 is buried (FIG. 3(c)). In such case, the gate electrode 110 is formed so that the width of the protruded portion in the side of the drain electrode 106 is longer as compared with the side of the source electrode 105. This provides a formation of the gap 112 between the side surface of the gate electrode 110 in the concave portion 113 and the side surface of the carrier-supplying layer 104.

Then, the passivation film 111 is deposited to cover the upper surfaces of the insulating film 107 and the gate electrode 110 in the region between the source electrode 105 and the drain electrode 106. The field effect transistor 100 shown in FIG. 1 is obtained by the above-described procedure.

Since the gate electrode 110 has no contact with the insulating film 107/carrier-supplying layer 104-interface containing a number of interface states formed therein, more specifically, for example, with the SiN/AlGaN interface according to the present embodiment, no leakage path through such interface is present, so that the Schottky characteristic is exhibited, in which all the gate current pass through the Schottky electrode-carrier-supplying layer 104 (for example, AlGaN layer). Thus, a reduced gate leakage current can be provided, allowing an operation at higher voltage and an operation at higher power.

Further, since the gaps 112 are provided in both of the side of the source electrode 105 and the side of the drain electrode 106 of the gate electrode 110 in the present embodiment, a gate leakage current can be further reduced with a certainty.

### Second Embodiment

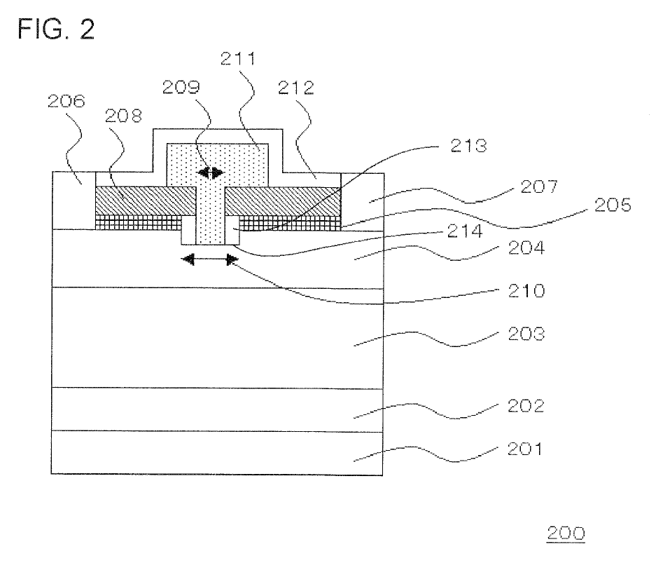

FIG. 2 is a cross-sectional view, illustrating a configuration of a field effect transistor in the present embodiment.

The basic configuration of a field effect transistor 200 shown in FIG. 2 is similar to that of the above-described field effect transistor 100 (FIG. 1) in first embodiment. In the field effect transistor 200, a buffer layer 202, a carrier-traveling layer 203 and a carrier-supplying layer 204 are also deposited on the substrate 201 in this sequence. Further, a source electrode 206 and a drain electrode 207 are provided on the carrier-supplying layer 204, and a gate electrode 211 of a recess gate structure is provided in a region between these electrodes. In a region between the source electrode 206 and the drain electrode 207, the upper surfaces of the insulating film 208 and the gate electrode 211 are coated with a passivation film 212.

However, in the present embodiment, a cap layer 205 is disposed between the carrier-supplying layer 204 and the insulating film 208. Further, a gap 213 in the side of the gate electrode 211 is provided to extend from the lower surface of the insulating film 208 over the entire side surface of the gate electrode 211.

Further, in the field effect transistor 200, a covering layer provided on the carrier-supplying layer 204 is a multiple-layered member having an insulating film (insulating film 208) containing silicon (Si) and nitrogen (N). Such multiple-layered member is composed of, for example, a group III-V nitride semiconductor layer (cap layer 205) and an insulating film 208 provided so as to contact on the cap layer 205.

Specific configurations of each of the layers will be described below. In the field effect transistor 200, typical material for the substrate 201 includes, for example, sapphire silicon carbide, GaN, AlN and the like.

Further, the buffer layer 202 is composed of a first group III-V nitride semiconductor material, and such material may typically include, for example, GaN, InN, AlN and a mixture of these three group III-V nitride semiconductor materials. However, a nucleation layer composed of GaN, InN, AlN and a mixture of these three group III-V nitride semiconductor materials may be disposed between the substrate 201 and the buffer layer 202 for forming the first semiconductor material. In addition, n-type impurity such as, for example, Si, S, O, Se and the like and/or p-type impurity such as, for example, Be, C, Mg and the like may be added in the first group III-V nitride semiconductor material.

The carrier-traveling layer 203 is composed of the second group III-V nitride semiconductor material, and such material may typically include, for example, GaN, InN, AlN and a mixture of these three group III-V nitride semiconductor materials. In addition, n-type impurity such as, for example, Si, S, O, Se and the like and/or p-type impurity such as, for example, Be, C, Mg and the like may be added in the second group III-V nitride semiconductor material. However, the impurity concentration may be preferably 1×10¹⁷ cm⁻³ or lower, in terms of more effectively reducing degradation in mobility of electron due to an influence of coulomb scattering caused by an increase in impurity concentration in the second group III-V nitride semiconductor material.

The carrier-supplying layer 204 is composed of the third group III-V nitride semiconductor material. The third group ILI-V nitride semiconductor material may be, composed of, for example, a wurtzite form group III-V nitride semiconductor material. Typical third group III-V nitride semiconductor material includes, for example, GaN, InN, AlN and a mixture of these three group III-V nitride semiconductor materials. Alternatively, AlGaN, InGaN, AlGaInN and the like may be employed for the third group III-V nitride semiconductor material. However, also in the present embodiment, the third group III-V nitride semiconductor material is composed of a material or a composition exhibiting smaller electron affinity than the second group III-V nitride semiconductor material. In addition, n-type impurity such as, for example, Si, S, O, Se and the like and/or p-type impurity such as, for example, Be, C, Mg and the like may be added in the third group III-V nitride semiconductor material.

The cap layer 205 is composed of a fourth group III-V nitride semiconductor material, and such material may typically include, for example, GaN, InN, AlN and a mixture of these three group III-V nitride semiconductor materials. However, in the present embodiment, the fourth group III-V nitride semiconductor material is composed of a material or a composition having larger electron affinity than the third group III-V nitride semiconductor material. The layer composed of such material is provided on the electron-supplying layer 204 between the gate electrode 211 and the drain electrode 207, so that negative polarized charge charge existing in the electron-supplying layer 204 can be kept away from the surface of the electron-supplying layer 204. Thus, a generation of a collapse can be effectively inhibited. In addition, n-type impurity such as, for example, Si, S, O, Se and the like and/or p-type impurity such as, for example, Be, C, Mg and the like may be added in the fourth group III-V nitride semiconductor material.

Further, typical material for the insulating film 208 includes, for example, materials listed as being employed for the insulating film 107 of the field effect transistor 100 of FIG. 1. More specifically, typical material for the insulating film 107 includes a chemical compound composed of one or more of Si, Mg, Hf, Al, Ti and Ta with one or more of O and N.

Further, typical material for the passivation film 212 includes a chemical compound composed of, for example, one or more of Si, Mg, Hf, Al, Ti and Ta with one or more of O and N. Further, an organic material such as an organic resin film and the like may be employed for the passivation film 212.

Next, a process for manufacturing the field effect transistor 200 will be described. The field effect transistor 200 may be manufactured by employing, for example, a process for manufacturing the field effect transistor 100 (FIG. 1).

First of all, the buffer layer 202 composed of the first group III-V nitride semiconductor material, the carrier-traveling layer 203 composed of the second group III-V nitride semiconductor material, the carrier-supplying layer 204 composed of the third group III-V nitride semiconductor material, and the cap layer 205 composed of the fourth group III-V nitride semiconductor material are formed in this sequence on the substrate 201.

Next, the cap layer 205 is selectively removed in regions for forming the source electrode 206 and the drain electrode 207 to expose the surface of the carrier-supplying layer 204. Then, the source electrode 206 and the drain electrode 207 are formed to be in contact with the carrier-supplying layer 204.

Then, in a region between the source electrode 206 and the drain electrode 207, the insulating film 208 that contacts the upper surface of the cap layer 205 is deposited.

Subsequently, in the region between the source electrode 206 and the drain electrode 207, predetermined regions of the insulating film 208 and the carrier supplying layer 204 are selectively removed to form a through hole extending through thereof and having a predetermined opening width 209, and a portion of the cap layer 205 is further removed to manufacture a recessed structure having a recess surface 214 of a predetermined recess width 210. In addition to above, when the recessed structure is formed, the concave portion is also formed so that the recess width 210 of the carrier-supplying layer 204 is larger than the width of the opening 209 in the insulating film 208 in the present embodiment. For example, the method described in first embodiment may be employed for forming the concave portion.

Then, the gate electrode 211 is formed, so that the through hole provided in the insulating film 208 is completely plugged, and that a region corresponding to the opening width 209 in the recessed structures is plugged. In such case, the gate electrode 211 is formed to protrude above the insulating film 208 from the inside of a recessed structure. Further, the gate electrode 211 is formed so that protruded width in the side of the drain electrode 207 is longer as compared with the side of the source electrode 206.

Further, in the region between the source electrode 206 and the drain electrode 207, the passivation film 212 that covers the entire device-forming surface of the substrate 201 is deposited. The field effect transistor 200 shown in FIG. 2 is obtained by the above-described procedure.

Since the side edge of the gate electrode 211 in the interface between the carrier-supplying layer 204 having piezo-electric charge and the cap layer 205 is spaced apart from the gate electrode 211 in the present embodiment, advantageous effects similar as obtained in first embodiment can also be obtained. Further, since the side edge of the gate electrode 211 in the interface between the cap layer 205 and the insulating film 208 is spaced apart from the gate electrode 211 in the present embodiment, in addition to the interface between the carrier-supplying layer 204 and the cap layer 205, the gate leakage current can be further effectively reduced.

### Third Embodiment

Yet other group III-V nitride semiconductor layer may further be provided on, and in contact with, the carrier-supplying layer 104 in the field effect transistor 100 shown in first embodiment (FIG. 1), and the gate electrode may be partially buried in such semiconductor layer.

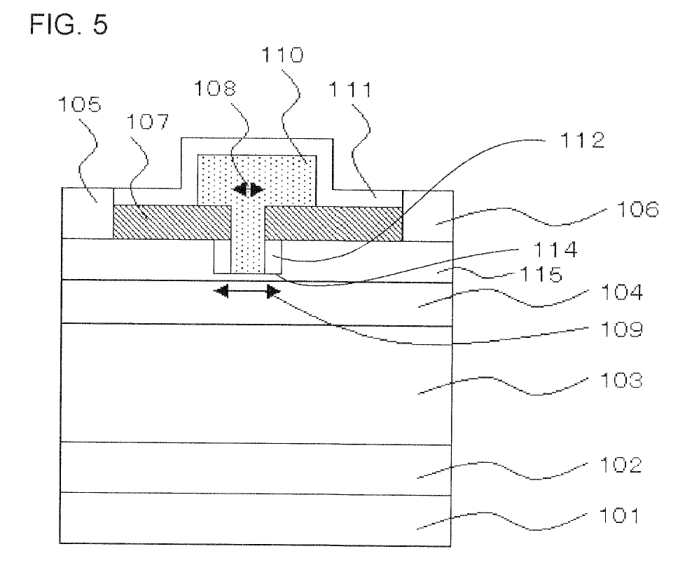

FIG. 5 is a cross-sectional view, illustrating a configuration of a field effect transistor of the present embodiment. While the basic configuration of a field effect transistor shown in FIG. 5 is similar to that of the above-described field effect transistor 100 shown in FIG. 1, a difference therebetween is that a multiple-layered member of the carrier-supplying layer 104 and the Schottky layer 115 provided on and in contact with the upper portion thereof is provided in place of the carrier-supplying layer 104 in FIG. 1. The source electrode 105 and the drain electrode 106 are provided so as to be in contact with the upper surface of the Schottky layer 115, and the gate electrode 110 is provided so as to be in contact with the recess surface 114 provided in the Schottky layer 115.

While a tensile strain is caused over the carrier-supplying layer 104 in a contact surface with the gate electrode 110 in first embodiment, a compressive strain is caused in a layer contacting with the gate electrode 110 in the group III-V nitride semiconductor layer structure in the present embodiment. More specifically, a compressive strain is caused in the Schottky layer 115. Such Schottky layer typically includes, for example, a GaN layer, an InGaN layer depending on the composition of the buffer layer and the carrier-supplying layer.

In the field effect transistor shown in FIG. 5, the side edge of the gate electrode 110 in the interface of the Schottky layer 115 and the insulating film 107 is spaced apart from the gate electrode 110, and the gap 112 is provided in the side surface of the gate electrode 110. Thus, advantageous effects similar as obtained in first embodiment can be obtained.

The end section of the interface that creates electric charge is spaced apart from the gate electrode 110 to reduce the gate leakage current in the configuration, in which positive charge is created in the group III-V nitride semiconductor layer structure (Schottky layer 115) in the interface with insulating film 107 as in the present embodiment, in addition to the configuration, in which negative charge is created in the group III-V nitride semiconductor layer structure (carrier-supplying layer 104) in the interface with insulating film 107 as in first embodiment.

Further, since the gate electrode 110 is provided so that the bottom surface thereof is in contact with the Schottky layer 115 in the present embodiment, further inhibition of the gate leakage current can be achieved, as compared with the configuration shown in FIG. 1.

While the preferred embodiments of the present invention has been fully described above in reference to the annexed figures, it is intended to present these embodiments for the purpose of illustrations of the present invention only, and various modifications other than that described above are also available.

For example, while the configuration, in which the side edge of the gate electrode in the interface of the carrier-supplying layer and the layer disposed immediately above thereof is spaced apart from the gate electrode, has been exemplarily described above, it may be sufficient to be configured that an interface of two selected from the carrier-supplying layer, the layer disposed immediately above thereof and the gate electrode is spaced apart from the other one. For example, it may be configured that an interface of the gate electrode and the carrier-supplying layer is spaced apart from the covering layer immediately above the carrier-supplying layer.

### EXAMPLES

In the following examples, a field effect transistor having an SiN film, which was provided over the carrier-supplying layer composed of from AlGaN directly or through the GaN layer therebetween, were manufactured.

### Example 1

The present example relates to the field effect transistor described in first embodiment. Description will be made below in reference to FIG. 1. A field effect transistor of the present example was manufactured by a procedure described in first embodiment.

In the present example, a c-plane ([0001] plane) silicon carbide (SiC) substrate was employed for the substrate 101.

An AlN layer (thickness: 200 nm) was employed for the first group III-V nitride semiconductor material constituting the buffer layer 102. A GaN carrier-traveling layer (thickness: 1000 nm) was employed for the second group III-V nitride semiconductor material constituting the carrier-traveling layer 103. Further, an AlGaN carrier-supplying layer (Al content ratio 0.3, thickness: 35 nm) was employed for the third group III-V nitride semiconductor material constituting the carrier-supplying layer 104.

Ti/Al (thickness of the Ti layer: 10 nm, thickness of Al layer: 200 nm) was employed for the source electrode 105 and the drain electrode 106. Further, Ni/Au (thickness of the Ni layer: 10 nm, thickness of Au layer: 200 nm) was employed for the gate electrode 110.

An SiN film (thickness: 80 nm) was employed for the insulating film 107, and the opening width 108 of the insulating film 107 was set to 500 nm. Further, a region of the upper surface of the third group III-V nitride semiconductor material 104 at a depth of 25 nm was removed to form a recess. The recess width 109 of the recess surface 114 was set to 520 nm.

Further, an SiON film (thickness: 80 nm) was employed for the passivation film 111.

The field effect transistor having such structure was manufactured, and it was found that the Schottky characteristic was exhibited, in which all the gate current pass through the AlGaN layer, and no leakage path through the SiN/AlGaN interface was created, since the gate electrode 110 was not in contact with the insulating film 107/carrier-supplying layer 104 interface or specifically the SiN/AlGaN interface, achieving a reduction in the gate leakage current.

While SiC was employed for the substrate in the present example, other type of substrate such as sapphire may alternatively be employed. Further, while the c-plane ([0001] plane) of the SiC substrate was utilized in the present example, the available plane may be that the growth of the group III-V nitride semiconductor proceeds with retaining its c-axis orientation and a piezoelectric effect is generated along a direction that is the same as in the present embodiment, and more specifically it may be inclined for an arbitrary orientation by about 55 degrees. However, since excessively larger inclination causes a difficulty in obtaining better crystallinity, it is preferable to provide an inclination for an arbitrary orientation within 10 degrees.

Similarly, while the GaN layer was employed for the carrier-traveling layer 103 in the present example, GaN, InN, AlN and a mixture of these three group III-V nitride semiconductor materials, such as an InGaN layer for the carrier-traveling layer 103 may be alternatively employed.

Similarly, a desired thickness may be alternatively employed for the thickness of each of the layers. However, since a lattice constant of each of the third and the fourth layers of the present example is not equivalent as a lattice constant of the second layer, it is preferable to employ a thickness that is smaller than the critical thickness for generating a dislocation.

Further, while no impurity is injected in the carrier-traveling layer 103 composed of GaN in the present example, n-type impurity such as, for example, Si, S, O, Se and the like and/or p-type impurity such as, for example, Be, C, Mg and the like may be injected. However, since excessively higher impurity concentration in the carrier-traveling layer 103 causes a degradation in mobility of electron due to an influence of coulomb scattering, the impurity concentration may more preferably be 1×10¹⁷ cm⁻³ or lower.

Further, while Ti/Al was employed for the source electrode 105 and the drain electrode 106 in the present example, a metal that is capable of creating an ohmic contact with AlGaN in the carrier-supplying layer 104 may be sufficient to be employed for the materials of the source electrode 105 and the drain electrode 106 in the present example, and for example, tungsten (W), molybdenum (Mo), Si, Ti, platinum (Pt), niobium (Nb), Al, gold (Au) and the like may be employed, or a structure having a plurality of these metals deposited may also be employed.

Similarly, while Ni/Au was employed for the metallic material of the gate electrode 110 in the present example, a desired metal may alternatively be employed as long as a Schottky contact is created with the group III-V nitride semiconductor material.

Further, while the portion over the depth of 25 nm from the surface of the third group III-V nitride semiconductor material was removed in the manufacture of the recessed structure in the present example, the removal for forming the recess may be conducted by any arbitrary depth of the semiconductor, and the removal may be conducted to remove the entire thickness of the third group III-V nitride semiconductor material. However, much smaller depth of the removed semiconductor deteriorates the effects for improving the breakdown voltage and for reducing electric current collapse achieved by employing the recessed structure, and on the other hand, much larger depth of the removed semiconductor reduces carrier in the region right under the gate electrode 110 to increase the electric resistance, and therefore the depth of the removed semiconductor material may be preferably within a range of from 30% to 70% of the originally deposited thickness of the semiconductor.

Further, while the opening width 108 was set to 500 nm and the length of the recess surface 114, namely the recess width 109 was set to 520 nm in the present example, the opening width 108, which corresponds to the gate length, may be set to a desired width depending upon the utilized frequency.

Further, the recess width 109 may be longer than the opening width 108, and may be set to a desired width. However, since much larger recess width 109 as compared with the opening width 108 tends to provide considerable electric current collapse according to the investigation of the present inventors, it is preferable that the difference between the recess width 109 and the opening width 108 is 100 nm, or in other words, the width of the gap 112 between the gate electrode 110 and the side surface of the recessed group III-V nitride semiconductor is preferably equal to or smaller than 50 nm.

Further, while the visor of the gate electrode 110 was formed to be longer in the side of the drain electrode 106 than in the side of the source electrode 105 in the present example, the visor in the side of the source 105 may be formed to be equivalent to or longer than, the visor in the side of the drain electrode 106. However, excessively longer visor in the side of the source electrode 105 may cause a larger decrease in the gain due to an increase in the gate capacitance over the advantageous effects of improving the breakdown voltage and reducing the electric current collapse, and thus is preferable to be shorter than the visor in the side of the drain electrode 106.

### Example 2

The present example relates to the field effect transistor described in second embodiment. Description will be made below in reference to FIG. 2. In the present example, a field effect transistor of the present example was manufactured by a procedure described in second embodiment.

In such case, a c-plane ([00001] plane) silicon carbide (SiC) substrate was employed for the substrate 201.

Further, an AlN layer (thickness: 200 nm) was employed for the first group III-V nitride semiconductor material constituting the buffer layer 202. A GaN carrier-traveling layer (thickness: 1000 nm) was employed for the second group III-V nitride semiconductor material constituting the carrier-traveling layer 203. An AlGaN carrier-supplying layer (Al content ratio 0.25, thickness: 40 nm) was employed for the third group III-V nitride semiconductor material constituting the carrier-supplying layer 204. Further, a GaN cap layer (thickness: 10 nm) was employed for the fourth group III-V nitride semiconductor material constituting the cap layer 205.

Further, Ti/Al (thickness of the Ti layer: 10 nm, thickness of Al layer: 200 nm) was employed for the source electrode 206 and the drain electrode 207. Further, Ni/Au (thickness of the Ni layer: 10 nm, thickness of Au layer: 200 nm) was employed for the gate electrode 211.

An SiON film (thickness: 80 nm) was employed for the insulating film 208, and the opening width 209 of the insulating film 208 was set to 700 nm. Further, regions of the third group III-V nitride semiconductor material and the fourth group III-V nitride semiconductor material at a depth of 20 nm were removed to form a recess. The recess width 210 was set to 780 nm.

Further, a SiON film (thickness: 80 nm) was employed for the material of the passivation film 212.

Such structure provides the Schottky characteristic, in which all the gate current pass through the AlGaN layer, and no leakage path through the AlGaN/GaN interface and the GaN/SiON interface, since the gate electrode 211 was not in contact with the carrier-supplying layer 204/cap layer 205 interface or specifically the AlGaN/GaN interface and the cap layer 205/insulating film 208 interface or specifically the GaN/SiON interface, achieving a reduction in the gate leakage current.

While SiC was employed for the substrate 201 in the present example, other type of substrate such as sapphire may alternatively be employed.

Further, while the c-plane ([0001] plane) of the SiC substrate was utilized in the present example, the available plane may be that the growth of the group III-V nitride semiconductor proceeds with retaining its c-axis orientation and a piezoelectric effect is generated along a direction that is the same as in the present embodiment, and more specifically it may be inclined for an arbitrary orientation by about 55 degrees. However, since excessively larger inclination causes a difficulty in obtaining better crystallinity, it is preferable to provide an inclination for an arbitrary orientation within 10 degrees.

Similarly, while the GaN layer was employed for the carrier-traveling layer 203 in the present example, GaN, InN, AlN and a mixture of these three group III-V nitride semiconductor materials, such as an InGaN layer for the carrier-traveling layer 203 may be alternatively employed.

Similarly, a desired thickness may be alternatively employed for the thickness of each of the layers. However, since a lattice constant of each of the third and the fourth layers of the present example is not equivalent as a lattice constant of the second layer, it is preferable to employ a thickness that is smaller than the critical thickness for generating a dislocation.

Further, while no impurity is injected in the carrier-traveling layer 203 composed of GaN in the present example, n-type impurity such as, for example, Si, S, O, Se and the like and/or p-type impurity such as, for example, Be, C, Mg and the like may be injected. However, the impurity concentration may preferably be 1×10¹⁷ cm⁻³ or lower, in view of inhibiting degradation in mobility of electron due to an influence of coulomb scattering caused by excessively higher impurity concentration in the carrier-traveling layer 203.

Further, while Ti/Al was employed for the source electrode 206 and the drain electrode 207 in the present example, a metal that is capable of creating an ohmic contact with AlGaN in the carrier-supplying layer 204 may be sufficient to be employed for the source electrode 206 and the drain electrode 207 in the present example, and for example, W, Me, Si, Ti, Pt, Nb, Al, Au and the like may be employed, or a structure having a plurality of these metals deposited may also be employed.

Similarly, while Ni/Au was employed for the gate electrode 211 in the present example, a desired metal may alternatively be employed as long as a Schottky contact is created with the group III-V nitride semiconductor material.

Further, while the portion over the depth of 20 nm from the surface of the third group III-V nitride semiconductor material was removed in the manufacture of the recessed structure in the present example, the removal for forming the recess may be conducted by any arbitrary depth of the semiconductor, and the removal may be conducted to remove the entire thickness of the third group III-V nitride semiconductor material.

However, excessively smaller depth of the removed semiconductor deteriorates the effects for improving the breakdown voltage and for reducing electric current collapse achieved by employing the recessed structure. On the other hand, much larger depth of the removed semiconductor reduces carrier under the gate to increase the electric resistance. Therefore the depth of the removed semiconductor material may be preferably within a range of from 30% to 70% of the originally deposited thickness of the semiconductor.

Further, while the opening width 209 was set to 700 nm and the length of the recess section, namely the recess width 210 of the recess surface 214 was set to 780 nm in the present example, the opening width 209, which corresponds to the gate length, may be set to a desired width depending upon the utilized frequency.

Further, the recess width 210 may be longer than the opening width 209, and may be set to a desired width. However, since much larger recess width 210 as compared with the opening width 209 tends to provide considerable electric current collapse according to the investigation of the present inventors, it is preferable that the difference between the recess width 210 and the opening width 209 is 100 nm, or in other words, the width of a gap between the gate electrode and the side surface of the recessed group III-V nitride semiconductor, namely the gap 213, is preferably equal to or smaller than 50 nm.

Further, while the visor of the gate electrode 211 was formed to be longer in the side of the drain electrode 207 than in the side of the source electrode 206 in the present example, the visor in the side of the source 206 may be formed to be equivalent to or longer than, the visor in the side of the drain electrode 207. However, excessively longer visor in the side of the source electrode 206 may cause a larger decrease in the gain due to an increase in the gate capacitance over the advantageous effects of improving the breakdown voltage and reducing the electric current collapse, and thus is preferable to be shorter than the visor in the side of the drain electrode 207.

1. A field effect transistor, comprising:
a group III-V nitride semiconductor layer structure containing a hetero junction;
a source electrode and a drain electrode formed on the group III-V nitride semiconductor layer structure to be spaced apart from each other;
a gate electrode arranged between said source electrode and said drain electrode; and
a covering layer provided over, and in contact with, said group III-V nitride semiconductor layer structure in a region between said gate electrode and said drain electrode or in a region between said source electrode and said gate electrode,
wherein said group III-V nitride semiconductor layer structure includes a group III-V nitride semiconductor layer, in which a strain is generated,
wherein a portion of said gate electrode is buried in said group III-V nitride semiconductor layer structure and is in contact with said group III-V nitride semiconductor layer having the strain generated therein, and
wherein a side edge of the gate electrode in an interface of said group III-V nitride semiconductor layer having the strain generated therein and said covering layer is spaced apart from said gate electrode.

2. The field effect transistor as set forth in claim 1,
wherein a concave portion is provided in said group III-V nitride semiconductor layer structure,
wherein said gate electrode is provided so as to be in contact with a bottom surface of said concave portion, and
wherein a gap is provided between a side surface of said gate electrode and a side surface of said concave portion in a cross-sectional view along the gate length.

3. The field effect transistor as set forth in claim 2,
wherein a length of said gap in a cross-sectional view along the gate length is larger than 0 nm and smaller than 50 nm.

4. The field effect transistor as set forth in claim 1,
wherein said covering layer is provided so as to be in contact with a side surface of said gate electrode, and
wherein a side surface of said group III-V nitride semiconductor layer structure is spaced apart from said gate electrode under a region in contact with said covering layer in a cross-sectional view along the gate length.

5. The field effect transistor as set forth in claim 1,
wherein said group III-V nitride semiconductor layer structure includes an electron-travelling layer and an electron-supplying layer provided over, and in contact with, said electron-travelling layer, and
wherein said source electrode and said drain electrode are provided so as to be in contact with said electron-supplying layer, and a portion of said gate electrode is buried in said electron-supplying layer.

6. The field effect transistor as set forth in claim 5, wherein said electron-travelling layer is a gallium nitride (GaN) layer and said electron-supplying layer is an aluminum gallium nitride (AlGaN) layer.

7. The field effect transistor as set forth in claim 1,
wherein said covering layer is an insulating film containing silicon (Si) and nitrogen (N).

8. The field effect transistor as set forth in claim 1,
wherein said covering layer is a multiple-layered member including an insulating film containing silicon (Si) and nitrogen (N).

9. The field effect transistor as set forth in claim 8, wherein said multiple-layered member is composed of a group III-V nitride semiconductor layer and said insulating film, said insulating film being provided on, and in contact with, said group III-V nitride semiconductor layer structure.

10. The field effect transistor as set forth in claim 1,
wherein a compressive strain is caused in a layer that is in contact with said gate electrode in said group III-V nitride semiconductor layer structure.

11. The field effect transistor as set forth in claim 1,
wherein said covering layer is provided on, and in contact with, a side surface of said gate electrode in the side of the drain electrode, and
wherein said gate electrode includes a field plate formed over said covering layer, said field plate being protruded toward the side of said drain electrode to form a visor-like shape.

12. The field effect transistor as set forth in claim 2,
wherein said group III-V nitride semiconductor layer structure includes an electron-travelling layer and an electron-supplying layer provided over, and in contact with, said electron-travelling layer, and
wherein said source electrode and said drain electrode are provided so as to be in contact with said electron-supplying layer, and a portion of said gate electrode is buried in said electron-supplying layer.

13. The field effect transistor as set forth in claim 3,
wherein said group III-V nitride semiconductor layer structure includes an electron-travelling layer and an electron-supplying layer provided over, and in contact with, said electron-travelling layer, and
wherein said source electrode and said drain electrode are provided so as to be in contact with said electron-supplying layer, and a portion of said gate electrode is buried in said electron-supplying layer.

14. The field effect transistor as set forth in claim 4,
wherein said group III-V nitride semiconductor layer structure includes an electron-travelling layer and an electron-supplying layer provided over, and in contact with, said electron-travelling layer, and
wherein said source electrode and said drain electrode are provided so as to be in contact with said electron-supplying layer, and a portion of said gate electrode is buried in said electron-supplying layer.

15. The field effect transistor as set forth in claim 2,
wherein said covering layer is an insulating film containing silicon (Si) and nitrogen (N).

16. The field effect transistor as set forth in claim 3,
wherein said covering layer is an insulating film containing silicon (Si) and nitrogen (N).

17. The field effect transistor as set forth in claim 4,
wherein said covering layer is an insulating film containing silicon (Si) and nitrogen (N).

18. The field effect transistor as set forth in claim 5,
wherein said covering layer is an insulating film containing silicon (Si) and nitrogen (N).

19. The field effect transistor as set forth in claim 6,
wherein said covering layer is an insulating film containing silicon (Si) and nitrogen (N).

20. The field effect transistor as set forth in claim 2,
wherein said covering layer is a multiple-layered member including an insulating film containing silicon (Si) and nitrogen (N).
